(19) United States
(12) Patent Application Publication
(10) Pub. No.: US 2025/0176331 A1
(43) Pub. Date: May 29, 2025

(54) DISPLAY DEVICE

(71) Applicant: AUO Corporation, Hsinchu City (TW)

(72) Inventors: Chia-Chun HSU, Hsinchu City (TW); Yu-Ping Kuo, Hsinchu City (TW); Hsiao-Wei Cheng, Hsinchu City (TW)

(21) Appl. No.: 18/959,707

(22) Filed: Nov. 26, 2024

(30) Foreign Application Priority Data
Nov. 29, 2023 (TW) 112146382

(51) Int. Cl. H10H 20/855; H10H 20/853

(52) U.S. Cl. CPC H10H 20/855; H10H 20/853

(57) ABSTRACT

A display device includes a display module and a decorative layer. The display module includes sub-pixels, and a line connecting the midpoints of any two opposite sides of each sub-pixel forms an auxiliary center line. The decorative layer has a through hole and is arranged above the display module. Each sub-pixel corresponds to n through holes, and n is a positive integer. When n is 1, the through hole is located within the coverage of the sub-pixel, and a first top view area of the sub-pixel is 1.5 times to 6 times a second top view area of the through hole. Or the sub-pixel is located within the coverage of the through hole, and the second top view area of the through hole is 1.5 times to 6 times the first top view area of the sub-pixel.

### CROSS-REFERENCE TO RELATED APPLICATION

This application claims priority to Taiwan Application Serial Number 112146382, filed Nov. 29, 2023, which is herein incorporated by reference in its entirety.

### BACKGROUND

### Field of Invention

The present disclosure relates to a display device. More particularly, the present disclosure relates to a display device that can improve the light transmittance of a light-emitting element.

### Description of Related Art

With the rapid development of smart technology, automobile users' demand for in-car displays is not limited to excellent optical performance. Traditional large screens, combined screens, and curved screens are no longer favored by the new generation of young people.

Automobile interior cockpits will develop in the direction of intelligence in the future, especially the overall aesthetics, technology and touch of the interior. Surface design will transform from decorative to multifunctional, combining decoration and function, and future smart surface displays integrated with interior exterior design will gradually become a highlight of vehicle interiors, attracting consumers' attention. In order to create the overall atmosphere of the car room space, most of the surfaces of the display devices have the decorative film that can present decorative patterns, such as wood grain, checkerboard decorative films, etc.

A large number of multi-functional smart surface decorative films have appeared on the market currently, such as lighting control decorative films, which are relatively mature. However, products used in automotive displays face many problems with optical effects.

The decorative film of the vehicle display screen forms a pattern by applying semi-transparent ink on the entire glass cover currently. When the display screen is off, by controlling the transmittance of the ink, the display screen is invisible and integrated with other interior parts of the car. When the screen is lit, the light will be absorbed when passing through the semi-transparent ink on the glass cover, resulting in color distortion of the display screen and overlapping of the displayed image with the ink pattern, thereby resulting in a decrease in image quality and directly affecting the display effect of the display screen.

### SUMMARY

The present disclosure provides a display device including a display module and a decorative layer. The display module includes a plurality of sub-pixels, and a line connecting the midpoints of any two opposite sides of each sub-pixel forms an auxiliary center line. The decorative layer has at least one through hole and is arranged above the display module. Each sub-pixel corresponds to n through holes, and n is a positive integer. When n is 1, the through hole is located within the coverage of the sub-pixel, and a first top view area of the sub-pixel is 1.5 times to 6 times a second top view area of the through hole. Or the sub-pixel is located within the coverage of the through hole, and the second top view area of the through hole is 1.5 times to 6 times the first top view area of the sub-pixel. Alternatively, when n is greater than or equal to 2, n through holes are arranged at equal intervals along the auxiliary center line.

According to one or more embodiments of the present disclosure, each sub-pixel has a size of a×b, each through hole has a size of w×t, and when n is greater than or equal to 2, 0<w<b/n and 0<t<a/n.

According to one or more embodiments of the present disclosure, when n is greater than or equal to 2, geometric centers of two of the n through holes are respectively aligned with midpoints of any two opposite sides of the sub-pixel.

According to one or more embodiments of the present disclosure, when n is greater than or equal to 2, the n through holes are arranged at equal intervals along a long side of the sub-pixel.

According to one or more embodiments of the present disclosure, when n is greater than or equal to 2, the n through holes are arranged at equal intervals along a short side of the sub-pixel.

According to one or more embodiments of the present disclosure, when n is greater than or equal to 2, the sub-pixels comprise a first sub-pixel and a second sub-pixel, the first sub-pixel corresponds to a first group of n through holes, the second sub-pixel corresponds to a second group of n through holes, the first group of n through holes are arranged at equal intervals along a long side of the first sub-pixel, and the second group of n through holes are arranged at equal intervals along a short side of the second sub-pixel.

According to one or more embodiments of the present disclosure, when n is greater than or equal to 2, the n through holes are arranged at intervals within the coverage of the sub-pixel.

According to one or more embodiments of the present disclosure, when n is greater than or equal to 2, the sub-pixels comprise a first sub-pixel, a second sub-pixel, and a third sub-pixel, the first sub-pixel corresponds to a first group of n through holes, the second sub-pixel corresponds to a second group of n through holes, and the third sub-pixel corresponds to a third group of n through holes, the first group of n through holes are arranged at equal intervals along a short side of the first sub-pixel, the second group of n through holes are arranged at equal intervals along a long side of the second sub-pixel, and the third group of n through holes are arranged at equal intervals along a short side of the third sub-pixel.

According to one or more embodiments of the present disclosure, when n is greater than or equal to 2, the sub-pixels comprise a first sub-pixel, a second sub-pixel, and a third sub-pixel, the first sub-pixel corresponds to a first group of n through holes, the second sub-pixel corresponds to a second group of n through holes, and the third sub-pixel corresponds to a third group of n through holes, the first group of n through holes are arranged at equal intervals along a short side of the first sub-pixel, the second group of n through holes are arranged at equal intervals along a short side of the second sub-pixel, and the third group of n through holes are arranged at equal intervals along a long side of the third sub-pixel.

According to one or more embodiments of the present disclosure, when n is greater than or equal to 2, the sub-pixels comprise a first sub-pixel, a second sub-pixel, and a third sub-pixel, the first sub-pixel corresponds to a first group of n through holes, the second sub-pixel corresponds to a second group of n through holes, and the third sub-pixel corresponds to a third group of n through holes, the first group of n through holes are arranged at equal intervals along a long side of the first sub-pixel, the second group of n through holes are arranged at equal intervals along a long side of the second sub-pixel, and the third group of n through holes are arranged at equal intervals along a short side of the third sub-pixel.

According to one or more embodiments of the present disclosure, the display device further includes an optical adhesive layer disposed between the display module and the decorative layer.

According to one or more embodiments of the present disclosure, the display device further includes a transparent cover disposed over the decorative layer.

According to one or more embodiments of the present disclosure, the display device further includes a transparent cover disposed over the decorative layer, and an optical adhesive layer disposed between the decorative layer and the transparent cover.

According to one or more embodiments of the present disclosure, the display device further includes an encapsulation layer covering the decorative layer.

The present disclosure further provides a display device, which includes a display module and a decorative layer. The display module includes a plurality of sub-pixels. The decorative layer has a plurality of through holes and is disposed over the display module. Each sub-pixel corresponds to four through-holes of the through-holes. Each of four corners of the sub-pixel is located within a coverage of the four through-holes in top view.

According to one or more embodiments of the present disclosure, each sub-pixel has a size of a×b, each through hole has a size of w×t, and 0<w<b and 0<t<a.

According to one or more embodiments of the present disclosure, geometric centers of the four through holes correspond to the four corners of the sub-pixel respectively.

According to one or more embodiments of the present disclosure, the display device further includes an optical adhesive layer disposed between the display module and the decorative layer.

According to one or more embodiments of the present disclosure, the display device further includes a transparent cover disposed over the decorative layer.

According to one or more embodiments of the present disclosure, the display device further includes a transparent cover disposed over the decorative layer, and an optical adhesive layer disposed between the decorative layer and the transparent cover.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a top view of a display device according to one embodiment of the present disclosure.

FIG. 2 is a cross-sectional view along line 2-2′ in FIG. 1.

FIGS. 3A, 3B, 3C, 3D, and 3E are top views of the corresponding relationships between sub-pixels and through holes in various embodiments of the present disclosure.

FIGS. 4A, 4B, and 4C are top views of the corresponding relationships between sub-pixels and through holes in various embodiments of the present disclosure.

FIG. 5 is a top view of the corresponding relationship between sub-pixels and through holes according to another embodiment of the present disclosure.

FIG. 6 is a cross-sectional view along line 2-2′ in FIG. 1 according to other embodiment of the present disclosure.

FIG. 7 is a cross-sectional view along line 2-2′ in FIG. 1 according to other embodiment of the present disclosure.

FIG. 8 is a top view of a display device according to another embodiment of the present disclosure.

FIG. 9 is a cross-sectional view along line 7-7′ in FIG. 8.

FIG. 10 is a top view of a display device according to yet another embodiment of the present disclosure.

FIG. 11 is a cross-sectional view along line 9-9′ in FIG. 10.

### DETAILED DESCRIPTION

Hereinafter, various embodiments will be described, and one of ordinary skill in the art of the present disclosure shall readily understand the spirit and principles of the present disclosure by referring to the description in conjunction with the figures. However, although the description specifically describes some specific embodiments, the embodiments are merely exemplary, and shall not be considered to be limitative or exhaustive in all aspects. Therefore, for one of ordinary skill in the art, various variants and modifications of the present disclosure made without departing from the spirit and principle of the present disclosure would be apparent and can be achieved easily.

In the accompanying drawings, for clarity, the thickness of layers, membranes, panels, areas, or the like is exaggerated. In the whole specification, the same referential numeral indicates the same element. It should be understood that when an element such as a layer, a membrane, an area, or a substrate is referred as “on” another element or “connected to” another element, the element may be directly on another element or directly connected to another element, or there may be an intermediate element. On the contrary, when an element is referred as “directly on another element” or “directly connected to” another element, there is not an intermediate element. As used herein, the “connection” may refer to physical and/or electric connection (coupling). Therefore, for “electric connection” or “coupling”, there may be another element between the two elements.

Further, relative terms such as “lower” or “bottom” and “upper” or “top” may be used herein for ease of description to describe one element's relationship to another element as shown in the figures. It will be understood that relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. Similarly, if the device in the figures is turned over, an element described as being “below” or “lower” relative to another element will then be “above” or “upper” relative to the other element. Thus, the term “below” encompasses both the below and above orientations depending on the spatial orientation of the device.

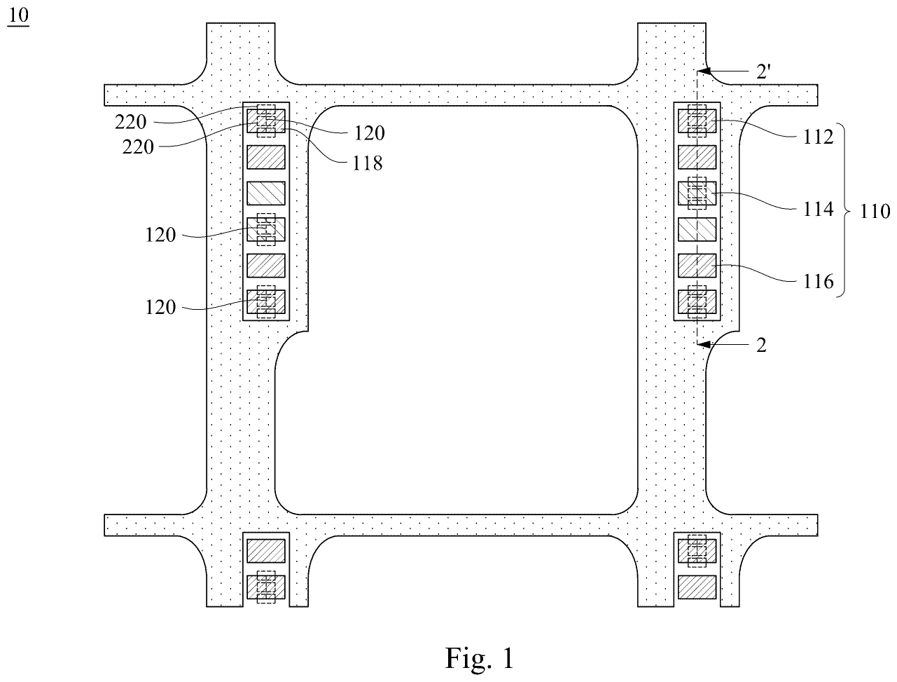

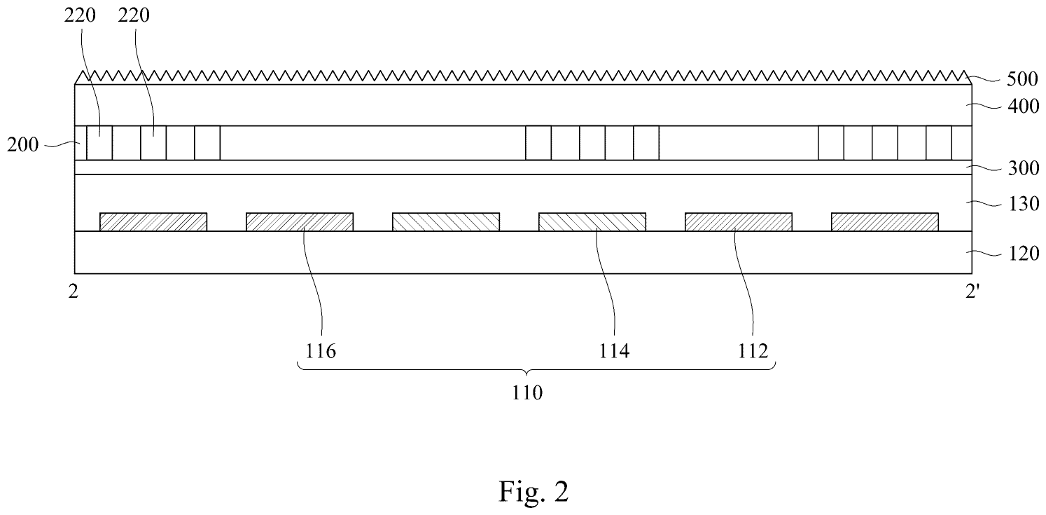

FIG. 1 is a top view of a display device 10 according to one embodiment of the present disclosure. FIG. 2 is a cross-sectional view along line 2-2′ in FIG. 1. Please refer FIG. 1 and FIG. 2, the display device 10 and 10a includes a display module 100 and a decorative layer 200. To be specific, the display module 100 includes a plurality of sub-pixels 110, and a line connecting the midpoints of any two opposite sides of each sub-pixel 110 forms an auxiliary center line 118. More specifically, the display module 100 at least includes a display substrate 120, a plurality of sub-pixels 110 on the display substrate 120, and an encapsulation layer 130 covering the plurality of sub-pixels 110. It can be understood that the display module 100 may have active light emitting display technology. For example, the display module 100 described in the present disclosure may have active light-emitting display technology applied to organic light emitting diodes (OLED), mini LED, or micro LED. The display technology of the display module 100 described in the present disclosure may also be reflective liquid crystal display technology or electronic paper (e-Paper) display technology. For example, the display technology of the display module 100 described in this disclosure may be a reflective liquid crystal display technology using super-twisted nematic display (STN display), or an electronic paper display technology using electrophoretic display (EPD). The present disclosure is not limited to the above application fields. A person having ordinary skill in the art can apply display technology with similar display effects to the display module proposed in the present disclosure without departing from the teachings of the disclosure. In this embodiment, the display module 100 takes a micro light-emitting diode display as an example.

These sub-pixels 110 can emit light of different color, such as red light, green light, and blue light. For example, these sub-pixels 110 include a first sub-pixel 112, a second sub-pixel 114, and a third sub-pixel 116, which can emit red light, green light, and blue light respectively. These sub-pixels 110 are arranged on the display substrate 120 in the order of emitting colors of blue, green, and red, for example, but are not limited thereto. In addition, in this embodiment, a single pixel includes two first sub-pixels 112, two second sub-pixels 114, and two third sub-pixels 116, in which one of the two sub-pixels with the same emitting color is an effective sub-pixel and the other one is a backup sub-pixel. That is to say, in the lighting test, the effective sub-pixels can be detected and judged whether their light emission has failed. If it fails, the spare sub-pixel is turned on for replacement.

In some embodiments, the plurality of sub-pixels 110 are, for example, micro light-emitting diodes, and their size is, for example, on the order of microns, for example, in the range of less than 100 microns and greater than 0 microns, but the present disclosure is not limited thereto. These micro light-emitting diodes can be first formed on a growth substrate (not shown), and then transfer to the display substrate 120 using mass transfer technology. In other embodiments, the plurality of sub-pixels 110 are, for example, sub-millimeter light-emitting diodes (Mini LEDs) or organic light-emitting diodes (OLEDs), but the present disclosure is not limited thereto.

In some embodiments, the encapsulation layer 130 may be anisotropic conductive film (ACF), ultraviolet glue, or silver glue, but not limited thereto.

Please continue to refer to FIG. 1 and FIG. 2, the decorative layer 200 is disposed over the display module 100. The decorative layer 200 has at least one through hole 220. To be specific, the at least one through hole 220 penetrates the decorative layer 200. In some embodiments, the at least one through hole 220 may be formed in the decorative layer 200 using laser drilling technology. In some embodiments, the shape of the at least one through hole 220 is similar to the shape of the sub-pixel 110. In other embodiments, the shape of the at least one through hole 220 may be different from the shape of the sub-pixel 110. More specifically, each sub-pixel 110 corresponds to n through holes, and n is a positive integer. It is worth noting that the corresponding through hole can be formed only over the effective sub-pixel after performing the lighting test as mentioned above. In this way, there is no need to spend extra cost to form a through hole over the spare sub-pixel. The corresponding relationship between each sub-pixel 110 and the through hole is described in detail below.

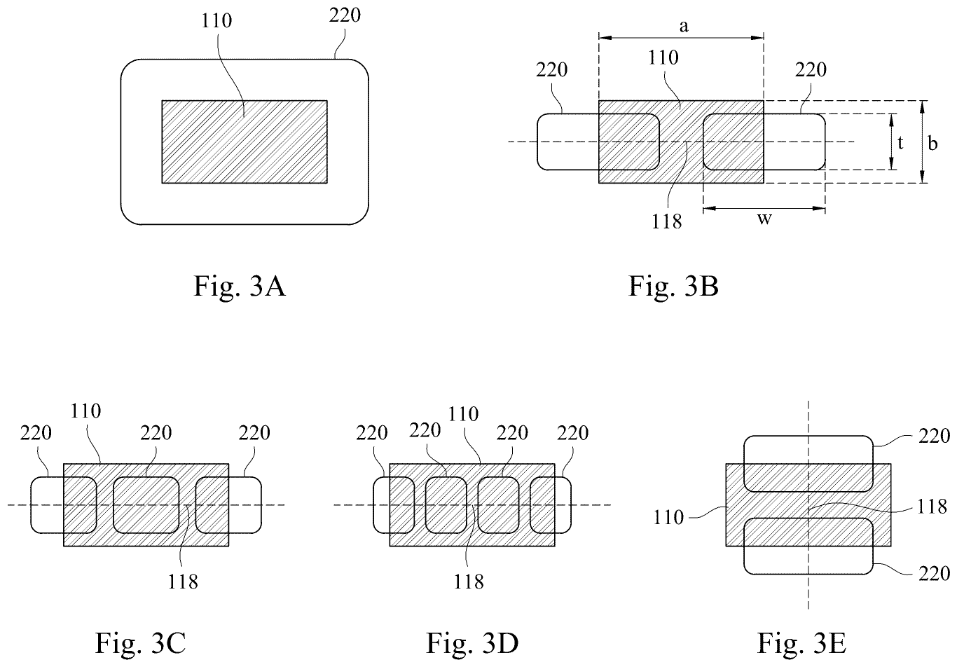

FIGS. 3A, 3B, 3C, 3D, and 3E are top views of the corresponding relationships between sub-pixels and through holes in various embodiments of the present disclosure. As shown in FIG. 3A, when n is 1 (that is, the number of through holes 220 is 1), in a top view, the sub-pixels 112/114/116 are located within the coverage of the through holes 220. In the top view, the sub-pixels 112/114/116 have a first top view area, the through hole 220 has a second top view area, and the second top view area is 1.5 times to 6 times the first top view are, such as 2 times, 2.5 times, 3 times, 3.5 times, 4 times, 4.5 times, 5.5 times or 6 times. In some embodiments, when the second top view area exceeds 6 times the first top view area, excessive size of the through hole 220 will cause the resolution of the decorative pattern to decrease. On the contrary, when the second top view area is less than 1.5 times the first top view area, the overall brightness of the display device cannot be effectively improved.

As shown in FIGS. 3B, 3C, 3D, and 3E, when n is greater than or equal to 2 (that is, the number of through holes 220 is greater than or equal to 2), these n through holes 220 are arranged at equal intervals along the auxiliary center line 118.

In some embodiments, each sub-pixel 110 has a size of a×b, each through hole 220 has a size of w×t, and when n is greater than or equal to 2, 0<w<b/n and 0<t<a/n.

In some embodiments, when n is greater than or equal to 2, geometric centers of two through holes 220 of the n through holes 220 are respectively aligned with midpoints of any two opposite sides of the sub-pixel 110.

In some embodiments, when n is greater than or equal to 2, the n through holes 220 are arranged at equal intervals along a long side of the sub-pixel 110.

In some embodiments, when n is greater than or equal to 2, the n through holes 220 are arranged at equal intervals along a short side of the sub-pixel 110.

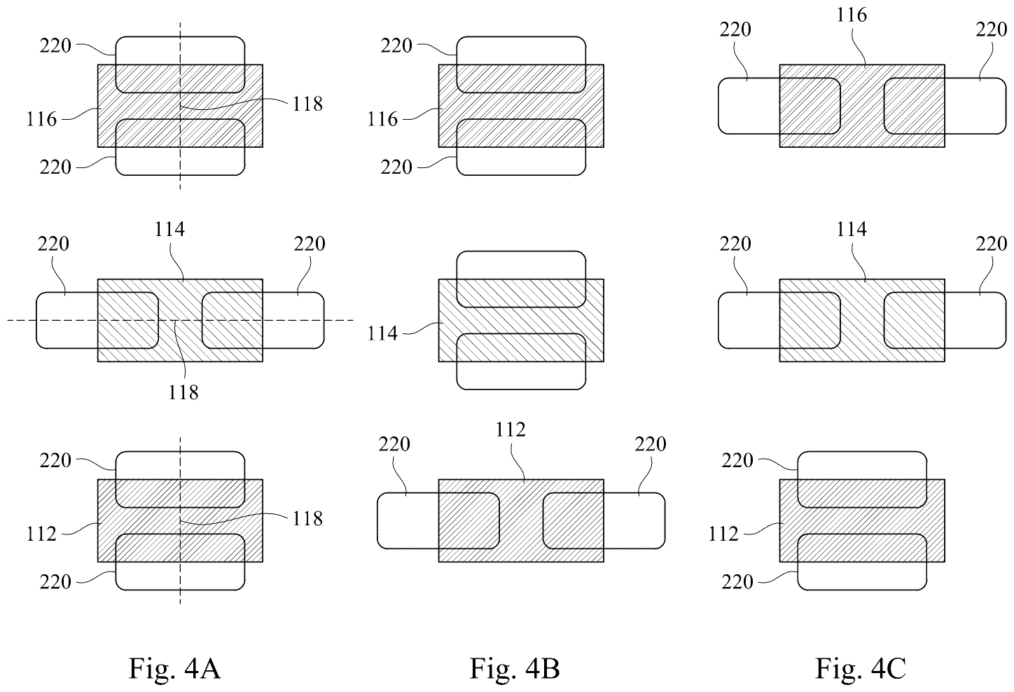

FIGS. 4A, 4B, and 4C are top views of the corresponding relationships between sub-pixels and through holes in various embodiments of the present disclosure. In some embodiments, when n is greater than or equal to 2, the sub-pixels 110 include a first sub-pixel 116 and a second sub-pixel 114. The first sub-pixel 116 corresponds to a first group of n through holes 220, the second sub-pixel 114 corresponds to a second group of n through holes 220, the first group of n through holes 220 are arranged at equal intervals along a long side of the first sub-pixel 116, and the second group of n through holes 220 are arranged at equal intervals along a short side of the second sub-pixel 114.

As shown in FIG. 4A, the sub-pixels 110 include a first sub-pixel 116, a second sub-pixel 114, a third sub-pixel 112, and a first group of n through holes 220, a second group of n through holes 220 and a third group of n through holes 220 corresponding to the first sub-pixel 116, the second sub-pixel 114 and the third sub-pixel 112, respectively. When n is greater than or equal to 2 ((that is, the number of through holes is greater than or equal to 2), the first group of n through holes 220 are arranged at equal intervals along the short side of the first sub-pixel 116 and along the auxiliary center line 118 of the first sub-pixel 116, the second group of n through holes 220 are arranged at equal intervals along the long side of the second sub-pixel 114 and along the auxiliary center line 118 of the second sub-pixel 114, and the third group of n through holes 220 are arranged at equal intervals along the short sides of the third sub-pixel 112 and along the auxiliary center line 118 of the third sub-pixel 112.

As shown in FIG. 4B, the sub-pixels 110 include a first sub-pixel 116, a second sub-pixel 114, a third sub-pixel 112, and a first group of n through holes 220, a second group of n through holes 220 and a third group of n through holes 220 corresponding to the first sub-pixel 116, the second sub-pixel 114 and the third sub-pixel 112, respectively. When n is greater than or equal to 2 ((that is, the number of through holes is greater than or equal to 2), the first group of n through holes 220 are arranged at equal intervals along the short side of the first sub-pixel 116 and along the auxiliary center line 118 of the first sub-pixel 116, the second group of n through holes 220 are arranged at equal intervals along the short sides of the second sub-pixel 114 and along the auxiliary center line 118 of the second sub-pixel 114, and the third group of n through holes 220 are arranged at equal intervals along the long side of the third sub-pixel 112 and along the auxiliary center line 118 of the third sub-pixel 112.

As shown in FIG. 4C, the sub-pixels 110 include a first sub-pixel 116, a second sub-pixel 114, a third sub-pixel 112, and a first group of n through holes 220, a second group of n through holes 220 and a third group of n through holes 220 corresponding to the first sub-pixel 116, the second sub-pixel 114 and the third sub-pixel 112, respectively. When n is greater than or equal to 2 ((that is, the number of through holes is greater than or equal to 2), the first group of n through holes 220 are arranged at equal intervals along the long side of the first sub-pixel 116 and along the auxiliary center line 118 of the first sub-pixel 116, the second group of n through holes 220 are arranged at equal intervals along the long side of the second sub-pixel 114 and along the auxiliary center line 118 of the second sub-pixel 114, and the third group of n through holes 220 are arranged at equal intervals along the short sides of the third sub-pixel 112 and along the auxiliary center line 118 of the third sub-pixel 112. It should be noted that the design of multiple through holes corresponding to different directions and configurations in the first sub-pixel 116, the second sub-pixel 114 and the third sub-pixel 112 in the same pixel can effectively improve the problem of moiré. Obviously, the present disclosure is not limited to the configurations of FIG. 4A, FIG. 4B and FIG. 4C.

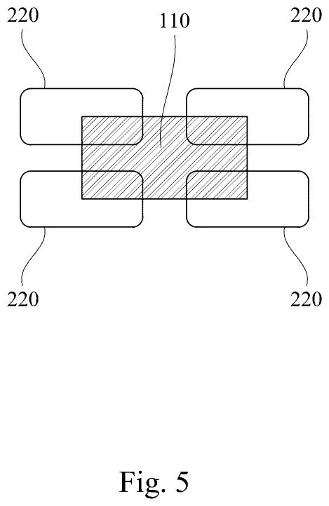

FIG. 5 is a top view of the corresponding relationship between sub-pixels and through holes according to another embodiment of the present disclosure. As shown in FIG. 5, when the number of through holes 220 corresponding to each sub-pixel 110 is four, the four corners of the sub-pixel 110 are each located within the coverage of the four through holes 220 in a top view. In this embodiment, the geometric centers of the four through holes 220 respectively correspond to the four corners of the sub-pixel 110. In this embodiment, each sub-pixel 110 has a size of a×b, each through hole 220 has a size of w×t, and 0<w<b and 0<t<a.

Returning to FIG. 2, the display device 10a further includes an optical adhesive layer 300 disposed between the display module 100 and the decorative layer 200. In some embodiments, the optical adhesive layer 300 may be, for example, optical clear adhesive (CA), hydrogels, or UV resin. It can be understood that the optical adhesive layer 300 is used to bond different layer structures in the display device and effectively reduce ambient light reflection.

As shown in FIG. 2, the display device 10a further includes a transparent cover 400 disposed on the decorative layer 200. In some embodiments, the material of the transparent cover 400 may be glass or polymethylmethacrylate (PMMA), which has a refractive index of 1.49.

As shown in FIG. 2, in order to eliminate the feeling that the glass cannot be close to the real decorative pattern, anti-glare (AG)/anti-reflective (AR) surface treatment can be performed on the surface of the transparent cover 400. Furthermore, the display device 10a may further include a feeling layer 500 disposed on the transparent cover 400. For example, a resin layer or a microstructure film can be coated on the transparent cover 400 to form the feeling layer 500.

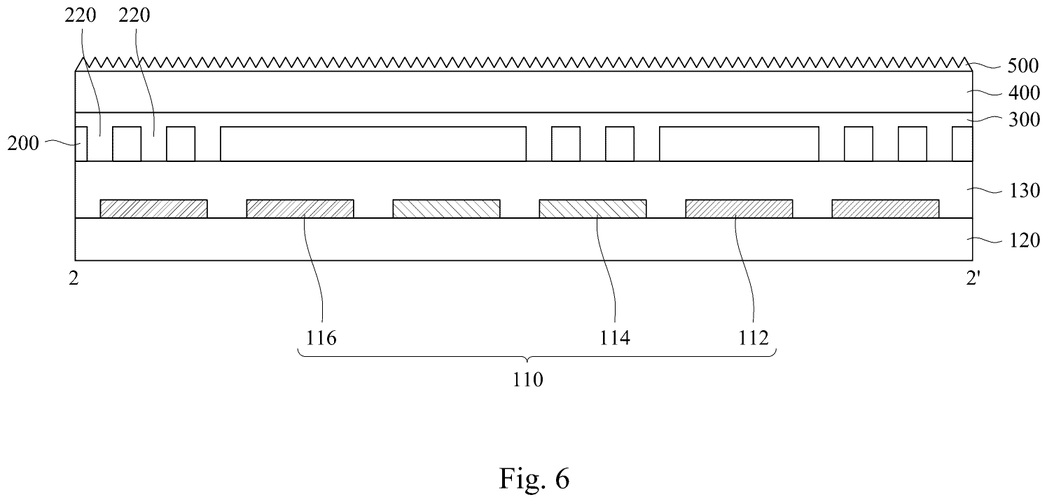

FIG. 6 is a cross-sectional view along line 2-2′ in FIG. 1 according to other embodiment of the present disclosure. As shown in FIG. 6, the difference between the display device 10a of FIG. 2 and the display device 10b of FIG. 6 is that the optical adhesive layer 300 is disposed between the decorative layer 200 and the transparent cover 400. More specifically, the optical adhesive layer 300 further extends into the through holes 220. In this embodiment, the decorative layer 200 is in direct contact with the display module 100.

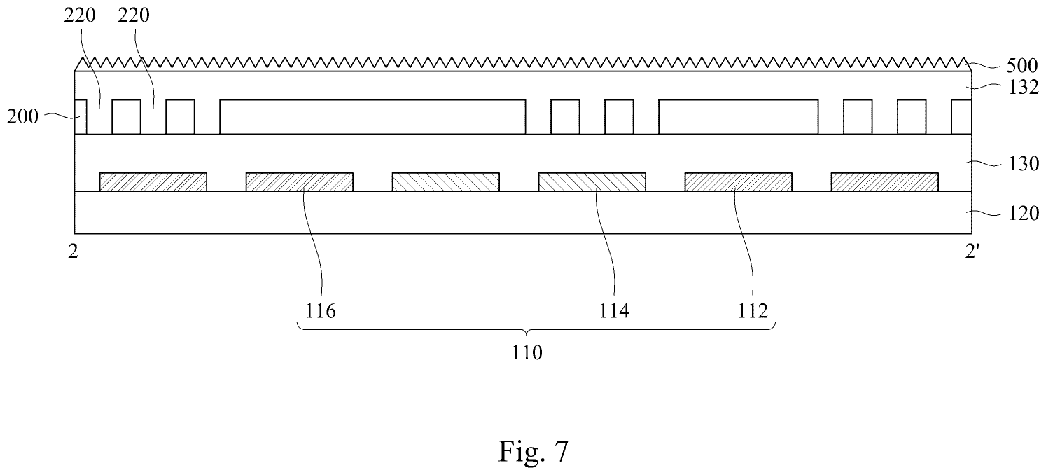

FIG. 7 is a cross-sectional view along line 2-2′ in FIG. 1 according to other embodiment of the present disclosure. As shown in FIG. 7, the difference between the display device 10b of FIG. 6 and the display device 10c of FIG. 7 is that the display device 10c further includes an encapsulation layer 132 covering the decorative layer 200, in which the encapsulation layer 132 further extends into the through holes 220. In this embodiment, the decorative layer 200 is in direct contact with the display module 100. Furthermore, the feeling layer 500 may be formed on the encapsulation layer 132. In other words, the feeling layer 500 and the encapsulation layer 132 may be formed in one. That is, the material of the feeling layer 500 is the same as that of the encapsulation layer 132. In some embodiments, the feeling layer 500 may be formed on the encapsulation layer 132 by nanoimprint lithography (NIL).

In some embodiments, the encapsulation layer 132 may be anisotropic conductive film (ACF), ultraviolet glue, or silver glue, but not limited thereto.

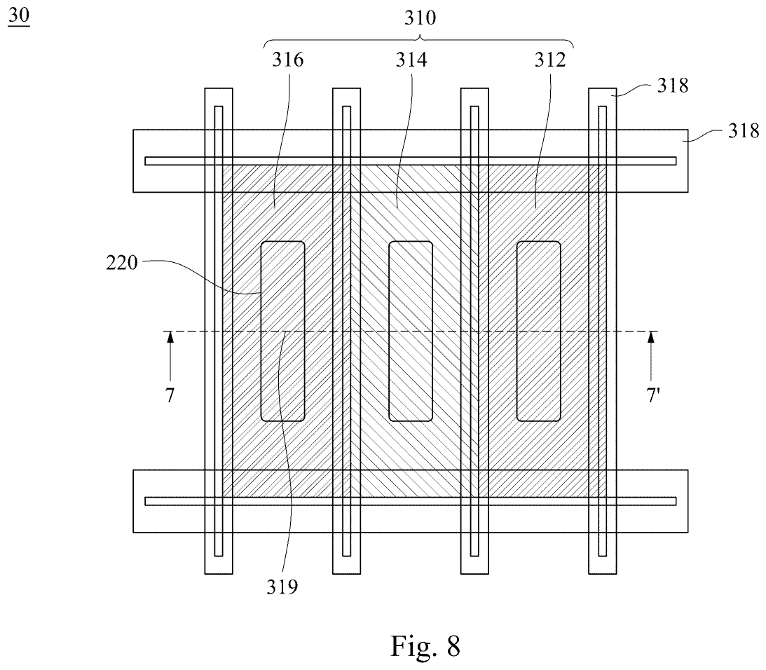

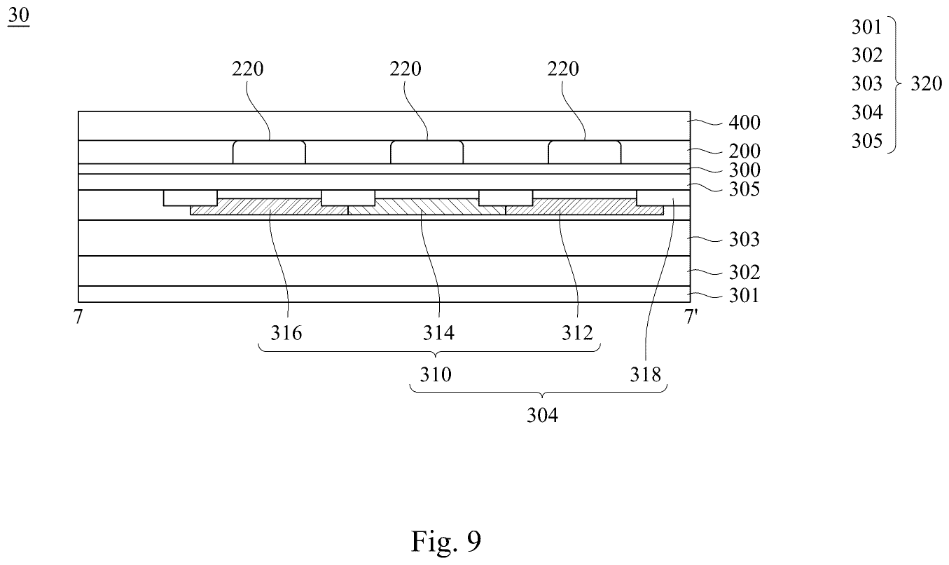

FIG. 8 is a top view of a display device according to another embodiment of the present disclosure. FIG. 9 is a cross-sectional view along line 7-7′ in FIG. 8. Please refer to FIG. 8 and FIG. 9, the display device 30 includes a display module 320 and a decorative layer 200. In this embodiment, the display module 320 takes a liquid crystal display (LCD) as an example. The display module 320 includes a plurality of sub-pixels 310, and a line connecting the midpoints of any two opposite sides of each sub-pixel 310 forms an auxiliary center line 319.

As shown in FIG. 9, more specifically, the display module 320 may at least include a polarizer 301, an array substrate 302, a liquid crystal layer 303, a color filter (CF) 304, and a polarizer 305 stacked in order from bottom to top. In some embodiments, the polarizer 301 and the polarizer 305 can both be linear polarizers, each having a transmission axis and selectively allowing light to pass through, and the configuration is such that the transmission axes of the two are orthogonal to each other. Alternatively, the polarizer 301 and the polarizer 305 can both be circular polarizers. In some embodiments, the array substrate 302 may be a glass array substrate or a flexible array substrate.

The color filter 304 may include a plurality of black matrices 318 and a plurality of sub-pixels 310, in which adjacent black matrices 318 have openings to accommodate the sub-pixels 310. Similarly, these sub-pixels 310 can emit different colors of light, such as red light, green light, and blue light. For example, these sub-pixels 310 include a first sub-pixel 312, a second sub-pixel 314, and a third sub-pixel 316, which can respectively emit red light, green light and blue light, and these sub-pixels 310 are arranged on the liquid crystal layer 303 in the order of emitting colors of blue, green, and red, for example, but not limited thereto.

The decorative layer 200 is disposed above the display module 320, and the decorative layer 200 has a plurality of through holes 220. To be specific, these through holes 220 penetrate the decorative layer 200. In some embodiments, these through holes 220 may be formed in the decorative layer 200 by laser drilling technology. More specifically, each sub-pixel 310 corresponds to n through holes, and n is a positive integer. The corresponding relationship between each sub-pixel 310 and the through hole is described in detail below.

As shown in FIG. 8 and FIG. 9, when n is 1 (that is, the number of through holes 220 is 1), the through hole 220 is located within the coverage of a single sub-pixel 312/314/316 in a top view. In a top view, the sub-pixel 312/314/316 has a first top view area, the through hole 220 has a second top view area, and the first top view area is 1.5 times to 6 times the second top view area, such as 2 times, 2.5 times, 3 times, 3.5 times, 4 times, 4.5 times, 5.5 times, or 6 times. In an embodiment where the number of through holes 220 is one, the through hole 220 is located within the coverage of the sub-pixels 312/314/316.

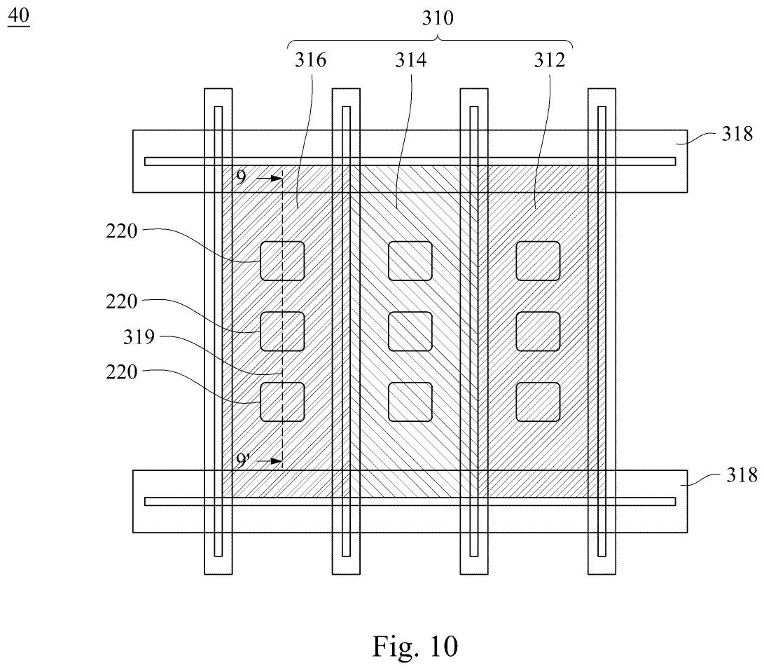

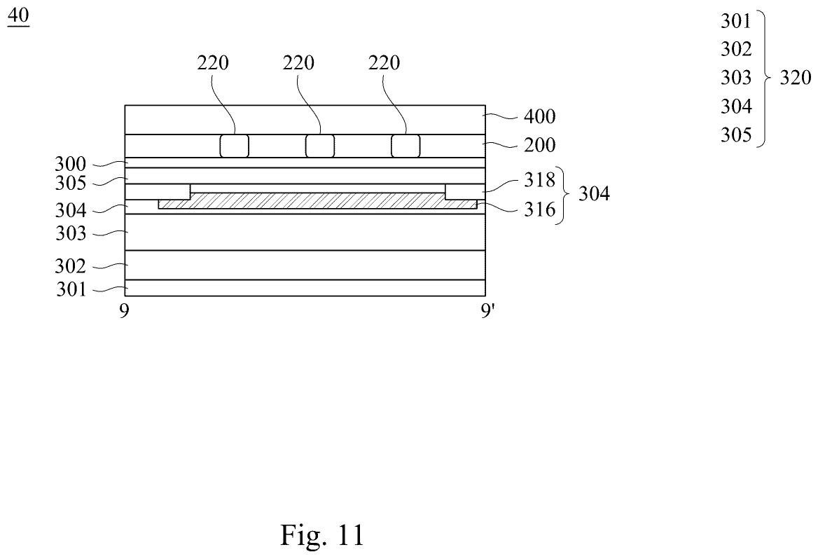

FIG. 10 is a top view of a display device according to yet another embodiment of the present disclosure. FIG. 11 is a cross-sectional view along line 9-9′ in FIG. 10. Please refer to FIG. 10 and FIG. 11, the difference between the display device 40 and the display device 30 is that each sub-pixel 312/314/316 included in the display module 320 in the display device 40 corresponds to a plurality of through holes 220. That is, a single sub-pixel corresponds to two or more through holes 220. In other words, when n is greater than or equal to 2 (that is, the number of through holes is 2 or greater than 2), the n through holes are arranged at equal intervals along the auxiliary center line 319.

In some embodiments, when n is greater than or equal to 2, the n through holes 220 are arranged at intervals within the coverage of the sub-pixels 312/314/316. In some embodiments, when n is greater than or equal to 2, the n through holes 220 are arranged at equal intervals along the long sides of the sub-pixels 312/314/316. In some embodiments, when n is greater than or equal to 2, the n through holes 220 are arranged at equal intervals along the short sides of the sub-pixels 312/314/316.

In some embodiments, if he display device 30/40 of the present disclosure adopts a transmissive or transflective design, a backlight module (not shown) may be further included to provide a areal light source, and the display module 320 is disposed on the backlight module.

In some embodiments, similarly, the display device 30/40 further includes an optical adhesive layer 300 disposed between the display module 320 and the decorative layer 200. In some embodiments, the optical adhesive layer 300 may be, for example, optical clear adhesive (CA), hydrogels, or UV resin. It can be understood that the optical adhesive layer 300 is used to bond different layer structures in the display device and effectively reduce ambient light reflection.

Similarly, the display device 30/40 may further include a transparent cover 400 disposed on the decorative layer 200. In some embodiments, the material of the transparent cover 400 may be glass or polymethylmethacrylate (PMMA), which has a refractive index of 1.49. In addition, in order to eliminate the feeling that the glass cannot be close to the real decorative pattern, anti-glare (AG)/anti-reflective (AR) surface treatment can be performed on the surface of the transparent cover 400. Furthermore, the display device 30/40 may further include a feeling layer 500 disposed on the transparent cover 400. For example, a resin layer or a microstructure film can be coated on the transparent cover 400 to form the feeling layer 500.

In summary, by forming through-holes corresponding to each sub-pixel in the decorative layer, the display device of the present disclosure can not only improve the brightness of the display device, but also enable the display device to achieve better luminous efficiency, thereby avoiding color aberration and excessive power consumption problems in the display device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A display device, comprising:
a display module comprising a plurality of sub-pixels, wherein a line connecting midpoints of any two opposite sides of each sub-pixel forms an auxiliary center line; and
a decorative layer having at least one through hole and arranged above the display module, each sub-pixel corresponding to n through holes, and n being a positive integer, wherein:
when n is 1,
the through hole is located within a coverage of the sub-pixel, and a first top view area of the sub-pixel is 1.5 times to 6 times a second top view area of the through hole, or
the sub-pixel is located within a coverage of the through hole, and the second top view area of the through hole is 1.5 times to 6 times the first top view area of the sub-pixel; or
when n is greater than or equal to 2,
n through holes are arranged at equal intervals along the auxiliary center line.

2. The display device of claim 1, wherein when n is greater than or equal to 2, each sub-pixel has a size of a×b, each through hole has a size of w×t, and 0<w<b/n and 0<t<a/n.

3. The display device of claim 1, wherein when n is greater than or equal to 2, geometric centers of two of the n through holes are respectively aligned with midpoints of any two opposite sides of the sub-pixel.

4. The display device of claim 1, wherein when n is greater than or equal to 2, the n through holes are arranged at equal intervals along a long side of the sub-pixel.

5. The display device of claim 1, wherein when n is greater than or equal to 2, the n through holes are arranged at equal intervals along a short side of the sub-pixel.

6. The display device of claim 1, wherein when n is greater than or equal to 2, the sub-pixels comprise a first sub-pixel and a second sub-pixel, the first sub-pixel corresponds to a first group of n through holes, the second sub-pixel corresponds to a second group of n through holes, the first group of n through holes are arranged at equal intervals along a long side of the first sub-pixel, and the second group of n through holes are arranged at equal intervals along a short side of the second sub-pixel.

7. The display device of claim 1, wherein when n is greater than or equal to 2, the n through holes are arranged at intervals within the coverage of the sub-pixel.

8. The display device of claim 1, wherein when n is greater than or equal to 2, the sub-pixels comprise a first sub-pixel, a second sub-pixel, and a third sub-pixel, the first sub-pixel corresponds to a first group of n through holes, the second sub-pixel corresponds to a second group of n through holes, and the third sub-pixel corresponds to a third group of n through holes, the first group of n through holes are arranged at equal intervals along a short side of the first sub-pixel, the second group of n through holes are arranged at equal intervals along a long side of the second sub-pixel, and the third group of n through holes are arranged at equal intervals along a short side of the third sub-pixel.

9. The display device of claim 1, wherein when n is greater than or equal to 2, the sub-pixels comprise a first sub-pixel, a second sub-pixel, and a third sub-pixel, the first sub-pixel corresponds to a first group of n through holes, the second sub-pixel corresponds to a second group of n through holes, and the third sub-pixel corresponds to a third group of n through holes, the first group of n through holes are arranged at equal intervals along a short side of the first sub-pixel, the second group of n through holes are arranged at equal intervals along a short side of the second sub-pixel, and the third group of n through holes are arranged at equal intervals along a long side of the third sub-pixel.

10. The display device of claim 1, wherein when n is greater than or equal to 2, the sub-pixels comprise a first sub-pixel, a second sub-pixel, and a third sub-pixel, the first sub-pixel corresponds to a first group of n through holes, the second sub-pixel corresponds to a second group of n through holes, and the third sub-pixel corresponds to a third group of n through holes, the first group of n through holes are arranged at equal intervals along a long side of the first sub-pixel, the second group of n through holes are arranged at equal intervals along a long side of the second sub-pixel, and the third group of n through holes are arranged at equal intervals along a short side of the third sub-pixel.

11. The display device of claim 1, further comprising an optical adhesive layer disposed between the display module and the decorative layer.

12. The display device of claim 11, further comprising a transparent cover disposed over the decorative layer.

13. The display device of claim 1, further comprising:
a transparent cover disposed over the decorative layer; and
an optical adhesive layer disposed between the decorative layer and the transparent cover.

14. The display device of claim 1, further comprising an encapsulation layer covering the decorative layer.

15. A display device, comprising:
a display module comprising a plurality of sub-pixels; and
a decorative layer having a plurality of through holes and disposed over the display module, each sub-pixel corresponding to four through-holes of the through-holes, wherein each of four corners of the sub-pixel is located within a coverage of the four through-holes in top view.

16. The display device of claim 15, wherein each sub-pixel has a size of a×b, each through hole has a size of w×t, and 0<w<b/n and 0<t<a.

17. The display device of claim 15, wherein geometric centers of the four through holes correspond to the four corners of the sub-pixel respectively.

18. The display device of claim 15, further comprising an optical adhesive layer disposed between the display module and the decorative layer.

19. The display device of claim 18, further comprising a transparent cover disposed over the decorative layer.

20. The display device of claim 15, further comprising:
a transparent cover disposed over the decorative layer; and
an optical adhesive layer disposed between the decorative layer and the transparent cover.
